(19) United States
(12) Patent Application Publication
(10) Pub. No.: US 2007/0122918 A1
(43) Pub. Date: May 31, 2007

(54) METHOD FOR FABRICATING MICROSTRUCTURE AND A MICROSTRUCTURE FORMED USING THE METHOD

(75) Inventors: Chin Sung PARK, Yongin-si (KR); Kyu Youn HWANG, Incheon (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD., Suwon-si (KR)

(21) Appl. No.: 11/538,119

(22) Filed: Oct. 3, 2006

(30) Foreign Application Priority Data
Oct. 4, 2005 (KR) 10-2005-93144

(51) Int. Cl. H01L 21/00

(52) U.S. Cl. 438/3

(57) ABSTRACT

A method for fabricating a microstructure includes forming a negative type photoresist film with a predetermined thickness on a substrate, removing solvent remaining in the photoresist film by a first heat treatment of the photoresist film, exposing the photoresist film with ultraviolet light having an energy of about 200 mJ/cm² to 400 mJ/cm² using a mask, performing a second heat treatment of the photoresist film at a temperature of about 75° C. to 85° C. for about 5 to 15 minutes and forming a photoresist pattern by developing the photoresist film.

This application claims priority to Korean Patent Application No. 2005-0093144 filed on Oct. 4, 2005, and all the benefits accruing therefrom under 35 U.S.C. § 119, the contents of which are herein incorporated by reference in its entirety.

### BACKGROUND OF THE INVENTION

1. Field of the Invention

The present invention relates to a method for fabricating a microstructure, and more particularly, to a method for fabricating a microstructure having a high aspect ratio by lithography process using photoresist.

2. Description of the Related Art

Studies in the fields of pathology, biotechnology, etc. such as disease diagnosis and assessment of the efficacy of drug therapy as future technologies are rapidly progressing. As one way of accelerating these studies, bio chips are being studied.

In a cell-binding chip used as a bio chip, it is useful to increase a surface area of a microstructure, to which a cell is to be bonded, in order to improve cell-binding efficiency. To increase the surface area of the microstructure, it is necessary to elevate the aspect ratio of spaces between patterns used for the microstructure as much as possible. As described above, the aspect ratio used herein refers to an aspect ratio of spaces between patterns.

If Microchem's SU-8 photoresist is applied as a negative type photoresist, it is possible to fabricate a microstructure by a single photoresist pattern formation process without any other process. Thus, the formation of a microstructure using photoresist is widely used.

FIG. 1 is a cross-sectional view for explaining a problem raised by a conventional method for fabricating a microstructure to form a high aspect ratio and FIG. 2 is a partial enlarged view showing a result of FIG. 1.

In order to form a high aspect ratio structure using SU-8 photoresist, a mask 10 with narrow spaces between photoresist patterns is used.

If the spaces between the photoresist patterns are relatively narrow, ultraviolet ray passing through transmission regions 11 of the mask 10 passes through exposed regions 30 of a photoresist film coated on a substrate 20 and may reach even to unexposed regions 40, which are not to be exposed to ultraviolet ray.

The unexposed regions 40 between the exposure regions 30 are partially exposed, thereby causing a defective pattern that leaves undesired residues 50 of the photoresist after developing the photoresist film as shown in FIG. 2.

A method of fabricating a microstructure while preventing such a defective pattern is disclosed in U.S. Pat. No. 6,558,868.

According to this patent, an absorbent substrate capable of absorbing ultraviolet ray without reflection is bonded to the bottom of a photoresist film so as to prevent the ultraviolet ray transmitted through the exposed regions 30 from being reflected and exposing the unexposed regions 40 of the photoresist film. However, the microstructure thus formed cannot increase the aspect ratio to more than 8, and the types of substrates useable as the absorbent substrate are restricted, so that there are limitations in applying the above patent technology to the practical manufacture of a microstructure.

FIG. 3 is a photograph showing the pattern defect caused by the conventional method for fabricating a microstructure.

If the thickness of the photoresist film used for ensuring a high aspect ratio becomes thicker, the top of the photoresist film is exposed to a relatively large amount of ultraviolet ray. This causes a defect of a “T-topping” phenomenon where the top portion of a photoresist pattern forms a T-shape as shown in the portion indicated as a quadrangle on the photograph of FIG. 3, thereby limiting the increase of the aspect ratio of the microstructure.

### BRIEF SUMMARY OF THE INVENTION

An exemplary embodiment provides a method for fabricating a microstructure having a relatively high aspect ratio, without the use of an ultraviolet ray absorbent layer, by changing the process condition of a photoresist exposure process.

An exemplary embodiment provides a method for fabricating a microstructure, which can reduce or effectively prevent the issuance of residues between the photoresist patterns or the issuance of a T-shaped defective pattern on the top portion while realizing a high aspect ratio.

In an exemplary embodiment there is provided a method for fabricating a microstructure including forming a negative type photoresist film with a predetermined thickness on a substrate, removing solvent remaining in the photoresist film by a first heat treatment of the photoresist film, exposing the photoresist film with ultraviolet light having an energy of about 200 mJ/cm² to about 400 mJ/cm² using a mask, performing a second heat treatment of the photoresist film at a heat treatment temperature of about 75° C. to 85° C. for about 5 to 15 minutes and forming a photoresist pattern by developing the photoresist film.

In an exemplary embodiment, the performing a second heat treatment is carried out at about 75° C. for about 15 minutes.

In an exemplary embodiment, the performing a second heat treatment is includes gradually increasing a start temperature up to the heat treatment temperature. The method for fabricating a microstructure may further include performing a third heat treatment hardening the photoresist pattern.

In an exemplary embodiment, an aspect ratio of the photoresist pattern is greater than 10 and a width of the photoresist pattern is greater than the spaces between the photoresist patterns.

### BRIEF DESCRIPTION OF THE DRAWINGS

FIG. 1 is a cross-sectional view for explaining a problem of a conventional method for fabricating a microstructure to form a high aspect ratio of the prior art;

FIG. 2 is a partial enlarged view showing a result of FIG. 1;

FIG. 3 is a photograph showing the pattern defect caused by the conventional method for fabricating a microstructure of the prior art;

FIG. 4 is a flowchart illustrating an exemplary embodiment of a method for fabricating a microstructure according to the present invention;

FIG. 5 is a perspective view of an electron micrograph of the microstructure formed by an exemplary embodiment of a method for fabricating a microstructure of the present invention;

FIGS. 6 and 7 are photographs of a plane view and a side view of FIG. 5, respectively;

FIG. 8 is a photograph of a cross section of an exemplary embodiment of a photoresist pattern that is formed when exposed at an exposure energy of 210 mJ/cm²;

FIG. 9 is a photograph of a cross section of an exemplary embodiment of a photoresist pattern that is formed when exposed at an exposure energy of 450 mJ/cm²; and

FIG. 10 is a perspective view of an exemplary embodiment of a photoresist pattern that is formed when a second heat treatment of a PEB process is performed at 75° C. for 3 minutes after being exposed at an exposure energy of 210 mJ/cm².

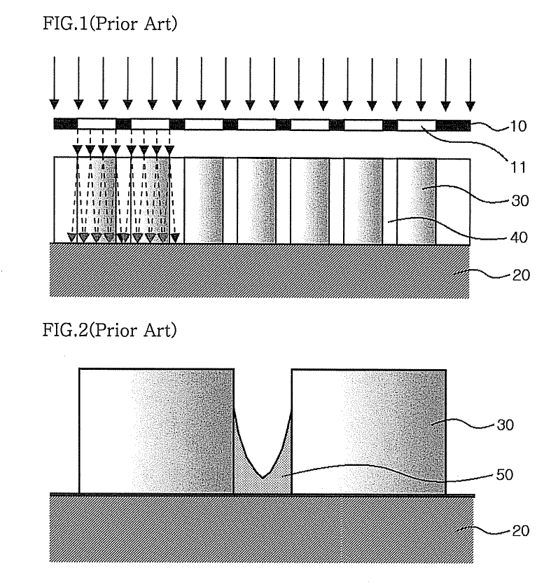

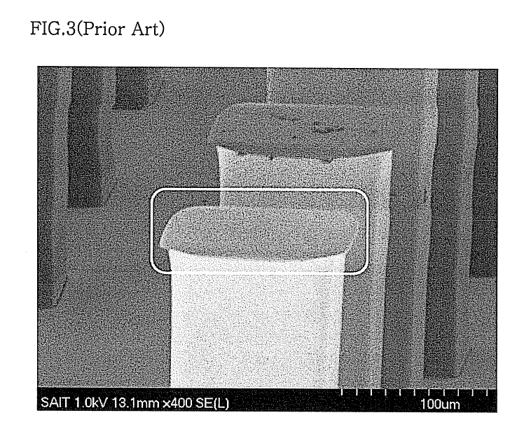

### DETAILED DESCRIPTION OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

The terminology used herein is for the purpose of describing particular embodiments only and is not intended to be limiting of the invention. The terms “a” and “an” do not denote a limitation of quantity, but rather denote the presence of at least one of the referenced item. The term “or” means “and/or”. The terms “comprising”, “having”, “including”, and “containing” are to be construed as open-ended terms (i.e., meaning “including, but not limited to”).

It will be understood that, although the terms first, second, third, etc., may be used herein to describe various elements, steps, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a preferred embodiment of the present invention will be described in detail with reference to the accompanying drawings.

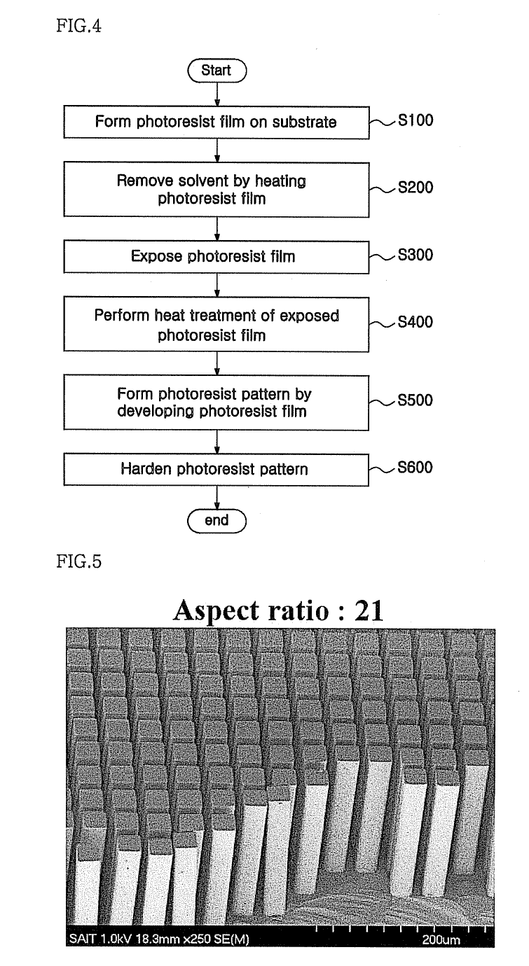

FIG. 4 is a flowchart illustrating an exemplary embodiment of a method for fabricating a microstructure according the present invention.

As shown in FIG. 4, according to the method for fabricating a microstructure, a photoresist is first coated on a substrate, such as by a spin coating method, to form a photoresist film (S100). In exemplary embodiments, a semiconductor substrate like silicon or a glass substrate may be used as the substrate, and the photoresist may be a negative type photoresist. In one exemplary embodiment, the photoresists is Microchem's SU-8 photoresist containing an epoxy component having an excellent surface adhesion and chemical resistance, which is applicable as a microstructure.

In exemplary embodiments, the thickness of the coated photoresist film can be varied from several μm to several hundreds of μm by adjusting the viscosity of the photoresist and the number of turns for coating.

In order to remove the solvent contained in the photoresist film, the photoresist film is heated. In an exemplary embodiment, a heat treatment of a soft bake at a high temperature along with the substrate is carried out. In one exemplary embodiment, the soft bake is carried out within a range of about 85° C. to about 95° C. depending on the thickness of the photoresist film coated on the substrate (S200).

The photoresist film on the substrate is exposed with ultraviolet ray by using a mask having a pattern of a microstructure (S300). A PEB (Post Exposure Bake) for heat treatment of the exposed photoresist film at a high temperature is carried out (S400).

In exemplary embodiments, the photoresist film is exposed with an ultraviolet ray having an energy of about 200 mJ/cm² to about 400 mJ/cm² depending on its thickness.

The PEB process serves to facilitate a cross-linking reaction so that the photoresist film exposed by ultraviolet ray transmitted through the mask does not react with a developing solution, thereby improving the resolution of a photoresist pattern.

In an exemplary embodiment of a method for fabricating a microstructure, the PEB process is carried out at a temperature less than about 85° C. to form a microstructure with an improved aspect ratio.

In one exemplary embodiment, in order to minimize a stress, wafer bending and photoresist film cracking which may occur in a heat treatment process, the PEB process to be carried out on the SU-8 photoresist includes gradually raising the temperature from a temperature less than 65° C. or carrying out a first heat treatment at a temperature less than about 65° C. and then a second heat treatment at a higher temperature.

In the illustrated exemplary embodiment, the second heat treatment is carried out at a temperature less than about 85° C., whereas the prior art performs such heat treatment at about 95° C. The photoresist is heated for more than about 5 minutes under the condition of the second heat treatment.

In one exemplary method, the heat treatment time is adjusted according to the thickness of the photoresist film and the heat treatment temperature is adjusted by carrying out the PEB process under the condition of the second heat treatment at 85° C. for more than about 5 minutes and at 75° C. for about 15 minutes.

Therefore, the second heat treatment of the PEB process is preferably carried out at a temperature of 75 to 85° C. for about 5 to 15 minutes.

The photoresist film in the region unexposed to ultraviolet ray is removed by developing the photoresist film, such as with a developing solution, to form a photoresist pattern (S500). The photoresist pattern is hardened at a relatively high temperature to achieve a microstructure (S600).

As in the illustrated exemplary embodiment, the photoresist pattern of the microstructure so formed can improve an aspect ratio, thereby ensuring an aspect ratio of greater than 10. Advantageously, even when the spaces between the photoresist patterns are smaller than the width of the photoresist pattern because of narrow spaces between the structures, a high aspect ratio of greater than 10 can be ensured.

In one exemplary embodiment, the developing solution is a dedicated SU-8 developing solution corresponding to the SU-8 photoresist. It is preferable that the heat treatment of the developed photoresist is performed at a high temperature greater than 150° C. to remove residual solvent while reducing or effectively preventing a change in the photoresist pattern and harden the structure of the photoresist pattern achieved by completing cross-linking. The heat treatment at a high temperature has an advantage that the adhesion between the substrate and the photoresist pattern is increased.

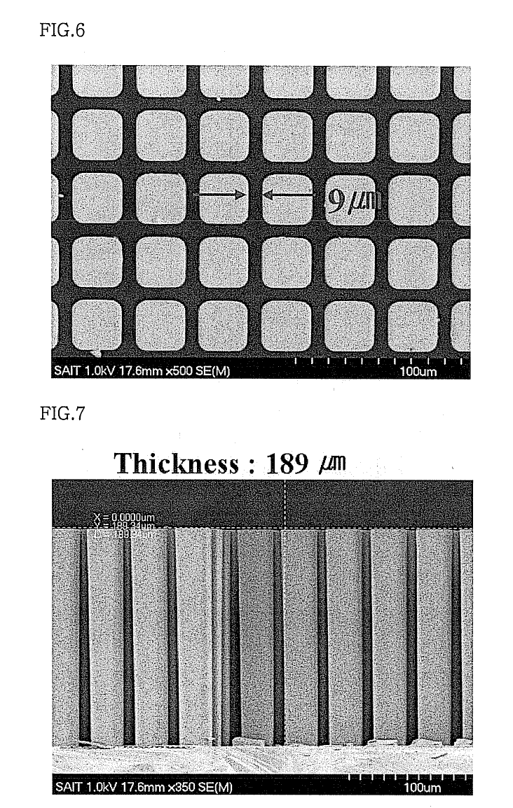

FIG. 5 is a perspective view of a scanning electron micrograph of the microstructure formed by an exemplary embodiment of a method for fabricating a microstructure of the present invention. FIGS. 6 and 7 are photographs of a plane view and a side view of FIG. 5, respectively.

As shown in the photographs of FIGS. 5 to 7, the structure formed by a method for fabricating a microstructure realizes an aspect ratio of 21 where the height is 189 μm and the distance between patterns is 9 μm.

The photoresist used is a SU-8 photoresist and the secondary heat treatment of the PEB process is carried out at a temperature of 75 to 85° C., thereby ensuring an optimum photoresist pattern. The photograph of FIG. 5 is obtained from the result of gradually increasing the temperature from 65° C. to 75° C. and then performing the secondary heat treatment at 75° C. for about 15 minutes.

In an exemplary embodiment where the microstructure as shown in FIG. 5 is a cell-binding chip used as a bio chip, the surface area of the cell-binding chip is increased by the relatively high aspect ratio, which enhances the cell-binding efficiency.

In an exemplary embodiment of a method of fabricating a microstructure of the present invention, a change in the microstructure according to a change in process condition will be described below.

In order to see a change of the photoresist pattern according to a change in exposure energy with respect to the SU-8 photoresist, the exposure energy is varied from about 210 mJ/cm² to about 450 mJ/cm², thus forming a microstructure.

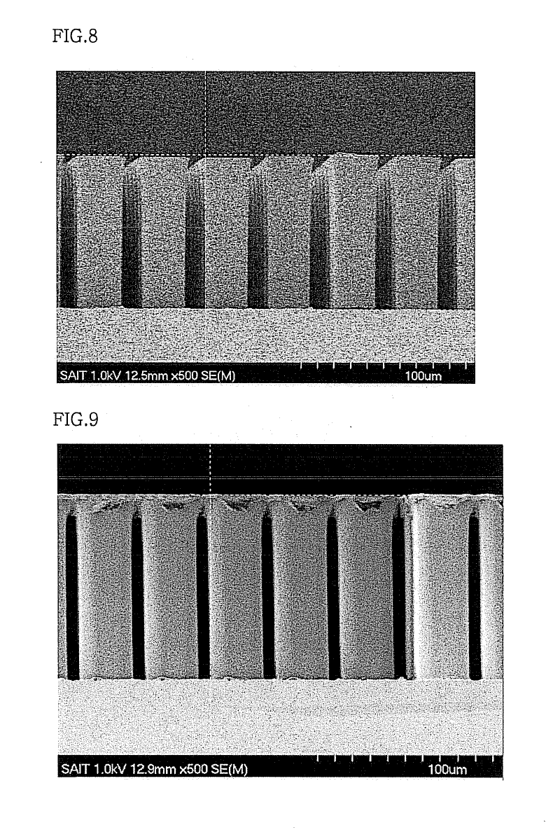

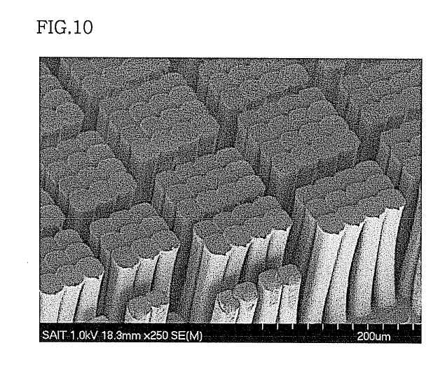

FIG. 8 is a photograph of a cross section of an exemplary embodiment of a photoresist pattern that is formed when exposed at an exposure energy of 210 mJ/cm² and FIG. 9 is a photograph of a cross section of an exemplary embodiment of a photoresist pattern that is formed when exposed at an exposure energy of 450 mJ/cm². The second heat treatment of the PEB process is performed on the photoresist at 75° C. for about 10 minutes. FIG. 10 is a perspective view of an exemplary embodiment of a photoresist pattern that is formed when the second heat treatment of the PEB process is performed at 75° C. for about 3 minutes after being exposed at an exposure energy of 210 mJ/cm².

As shown in the photograph of FIG. 8, if the exposure energy is 210 mJ/cm², a normal photoresist pattern is formed, while, as shown in the photograph of FIG. 9, if the exposure energy is excessive, for instance, 450 mJ/cm², a defective pattern is occurred due to a T-topping phenomenon.

FIG. 10 shows that if the heat treatment time of the PEB process is relatively short, the hardening of the photoresist pattern after the cross-linking is not sufficient, which causes a phenomenon that microstructures get tangled with each other.

Therefore, in order to form a photoresist pattern having a high aspect ratio without any defect, the exposure energy and the time of the PEB process should be adjusted accordingly.

As in the illustrated exemplary embodiments of a method of fabricating a microstructure of the present invention, the following effects are achieved.

In an exemplary embodiment of a method of fabricating a microstructure of the present invention, a microstructure having an aspect ratio of maximum 21 can be formed, without using a separate ultraviolet ray absorbent layer, by the temperature of a PEB process is about 85° C. or less.

According to an exemplary embodiment, a microstructure can be easily formed which has a relatively high aspect ratio while reducing or effectively preventing the issuance of residues between the photoresist patterns or the issuance of a T-shaped defective pattern on the top portion.

While the present invention has been particularly shown and described with reference to exemplary embodiments thereof, it will be understood by those of ordinary skill in the art that various changes and modifications may be made in the form and details of the described embodiments without departing from the spirit and scope of the invention as defined by the appended claims.

What is claimed is:

1. A method for fabricating a microstructure, the method comprising:
forming a negative type photoresist film with a predetermined thickness on a substrate;
removing solvent remaining in the photoresist film by a first heat treatment of the photoresist film;
exposing the photoresist film with ultraviolet ray having an energy of about 200 mJ/cm² to 400 mJ/cm² using a mask;
performing a second heat treatment of the photoresist film at a heat treatment temperature of about 75° C. to about 85° C. for about 5 to 15 minutes; and
forming a photoresist pattern by developing the photoresist film.

2. The method according to claim 1, wherein the performing a second heat treatment is carried out at about 75° C. for about 15 minutes.

3. The method according to claim 1, wherein the performing a second heat treatment includes gradually increasing a start temperature up to the heat treatment temperature.

4. The method according to claim 3, wherein the start temperature is less than about 65° C.

5. The method according to claim 1, further comprising performing a third heat treatment hardening the photoresist pattern.

6. The method according to claim 1, wherein the aspect ratio of the photoresist pattern is greater than 10 and the width of the photoresist pattern is greater than the spaces between the photoresist patterns.

7. A microstructure comprising:
a photoresist pattern including an aspect ratio of the photoresist pattern greater than 10 and a width of the photoresist pattern greater than spaces between the photoresist pattern, wherein:
a negative type photoresist film with a predetermined thickness is formed on a substrate;
solvent remaining in the photoresist film is removed in a first heat treatment of the photoresist film;
the photoresist film is exposed to ultraviolet ray having an energy of about 200 mJ/cm² to 400 mJ/cm² using a mask;
a second heat treatment of the photoresist film is performed at a heat treatment temperature of about 75° C. to about 85° C. for about 5 to 15 minutes; and
the photoresist pattern is formed by developing the photoresist film.
